(19) United States
(12) Patent Application Publication
(10) Pub. No.: US 2004/0129199 A1
(43) Pub. Date: Jul. 8, 2004

(54) Optimal crystallization parameter determination process

(76) Inventors: David T. Hamrick, Glencoe, AL (US); Lawrence W. Cosenza JR., Birmingham, AL (US); Nikolai Chernov, Birmingham, AL (US)

Correspondence Address: Gifford, Krass, Groh, Sprinkle,, Anderson & Citkowski, P.C., Suite 400, 280 N. Old Woodward Avenue, Birmingham, MI, 48009-5394, US

(21) Appl. No.: 10/665,453

(22) Filed: Sep. 19, 2003

Related U.S. Application Data
(60) Provisional application No. 60/412,337, filed on Sep. 20, 2002.

(51) Int. Cl. C30B 33/06

(52) U.S. Cl. 117/1

(57) ABSTRACT

A crystallization parameter optimization process includes self-learning programs based on neural networks or smart algorithms that divine optimal crystallization conditions. The operation of these programs is ideally coupled with a high throughput automated crystallization experiment system. Through the use of successful as well as unsuccessful crystallization experimental samples, the programs are efficiently able to predict optimal crystallization variables after sampling only a modest fraction of all possible variable permutations.

### RELATED APPLICATION

This application claims priority of U.S. Provisional Patent Application Serial No. 60/412,337 filed Sep. 20, 2002, which is incorporated herein by reference.

### FIELD OF THE INVENTION

The present invention relates in general to determining crystallization parameters for a sample, and in particular to the use of a self-learning crystallization optimization function for determining crystallization parameters from a large set of possible permutations.

### BACKGROUND OF THE INVENTION

Typically, a crystal grower attempts to crystallize as sample commercially available screens such as those available from Hampton Research, Emerald Biosystems, and Jena Bioscience. In the absence of a suitable crystal being grown or positive result from a screen, the crystal grower will try another screen, and so on until they exhaust the available screens. The vast majority of proteins (80-90%) never yield suitable crystals for structure determination via x-ray diffraction (Lamzin, V. S. and Perrakis, A. Current state of automated crystallographic data analysis. Nature Structural Biology, Structural Genomics Supplement, 2000, 978-981). If the crystal grower is lucky and obtains a crystal, the crystal often is small and plagued with defects, thereby rendering the crystal unsuitable for x-ray diffraction. The crystal grower then attempts to create a set of crystallization experiments around the condition that yielded the small imperfect crystal in order to grow large, defect-free crystals by a process called optimization. Usually, a linear grid screen that varies 1 or 2 variables such as pH or precipitating agent is used around the small crystal growth parameter hit. The optimization conditions often are laboriously hand-prepared. Typically, only positive results are recorded, with the vast majority of negative crystallization outcomes being discarded. The negative crystallization outcomes are usually physically classified in groups such as clear drop, phase change, precipitate, and spherulettes. The few proteins that ultimately yield crystals may take months or even years to crystallize.

Optimization of protein crystal growth have been performed using multivariate designs such as central composite, Box-Behnken and full factorial and incomplete factorial. These designs systematically evaluate several variables around a central point or within a range (Box, G. E. P. and Hunter, J. S. Ann. Math Statist. 1957, 28:195; Box, G. E. P., and Behnken, D. W. Technometrics 1960, 2:455; Box, G. E. P., Hunter, W. G, and Hunter, J. S. “Statistics for Experimenters.” Wiley Interscience, New York, 1978; Carter Jr., C. W., and Carter, C. W. Protein crystallization using incomplete factorial experiments. J. Biol. Chem. 1979, 254:12219-12223; Carter Jr., C. W. Response surface methods for optimizing and improving reproducibility of crystal growth. Methods in Enzymology 1997, 276: 74-99; and Shaw Stewart, P. D., and Baldock, P. F. M. Practical experimental design techniques for automatic and manual protein crystallization. J. Crys. Growth 1999, 196:665-673).

A comprehensive model for protein crystallization does not exist. The optimization methods identify user-defined variables in a systematic procedure to determine those variables most important for the particular protein sample to crystallize. There usually are four variables that are common to all protein crystallization experiments: protein and precipitant concentration, pH, and temperature. However, often there are more variables than currently can be evaluated. If possible, it is wise to select a variable that has a linearly independent effect on protein crystal growth (Box, G. E. P., Hunter, W. G, and Hunter, J. S. “Statistics for Experimenters.” Wiley Interscience, New York, 1978). In order to model the protein crystallization data the results are scored. Hence, the experience of a crystal grower plays an important role in the subjective assessment of data and ultimately the successful crystallization of a protein. Thus, there exists a need for a process for objectively screening a multi-dimensional parameter space incorporating all outcomes to rapidly identify optimal crystallization parameters.

### SUMMARY OF THE INVENTION

A crystallization parameter optimization process includes the steps of selecting multiple, physical characterization input variables to define a total crystallization experiment permutation number for a crystallant. A series of crystallization experimental samples are performed with the total number of samples being less than the permutation number. A predictive crystallization function if trained through analysis of the crystallization experimental samples that have been run. An optimal physical crystallization parameter is determined based on the predictive crystallization function.

A crystallization parameter optimization process also includes the step selecting multiple physical characterization input variables for a known crystallant to define a total crystallization experiment permeation number. Multiple crystallization experimental samples are performed on the known crystallant. A predictive crystallization function is trained through analysis of the multiple crystallization experimental samples. The predictive crystallization function is used to determine optimal physical crystallization parameters for the known crystallant. The optimal physical crystallization parameters and a physical property of the known crystallant are stored in a classification system. A comparison between an unknown crystallization sample to the classification of the known crystallant is used to optimize crystallization parameters for the unknown crystallization sample. In particular, protein crystals are grown through the use of crystallization parameter optimization processes as detailed herein.

A neural network is readily trained through analysis of the multiple crystallization experimental samples to predict optimal crystallization conditions for a protein.

A system for crystallization parameter optimization includes a database containing multiple input variables, each of which has a value range. The system also includes an incomplete factorial screen program including a trainable predictive crystallization function. A computer is provided that is capable of executing the incomplete factorial screen program to determine an optimal crystallization parameter. In addition, the system includes a manufacturing execution system for automatic acquisition of data from each of the crystallization experimental samples, as well as the analysis and archiving of data from the incomplete factorial screen program.

### BRIEF DESCRIPTION OF THE DRAWINGS

FIG. 1 is a schematic depiction of a system for carrying out the present invention;

FIG. 2 is a schematic illustrating a trained neural network according to the present invention for the exemplary lactoglobulin protein crystallization test;

FIG. 3 is a graph of neural network training incomplete factorial experiments as a function of score for the network based on the scoring scheme of Table 3 depicted in FIG. 2, where actual values are depicted as a solid line and network predicted values are depicted as a hashed line;

FIG. 4 is a graph of neural network crystallization predicted scores derived for experiments unseen by the trained network of FIG. 3 where predicted scores are depicted as hashed lines, as compared to actual measured scores depicted as solid lines;

FIG. 5 is a photograph illustrating the actual physical crystallization outcomes of the two predicted crystallization conditions for experiments 322 and 340 of the lactoglobin crystallization of FIG. 4;

FIG. 6 is a graph of neural network training incomplete factorial experiments as a function of score for an unknown protein based on a binary scoring scheme, where actual values are depicted as a solid line and network predicted values are depicted as a hashed line;

FIG. 7 is a graph of neural network crystallization predicted scores derived for the unknown protein experiments unseen by the trained network of FIG. 6 where predicted scores are depicted as hashed lines, as compared to actual measured scores depicted as solid lines;

FIG. 8 is a photograph illustrating the actual physical crystallization outcomes of the predicted crystallization condition for experiments 350 of the unknown protein crystallization of FIG. 7;

FIG. 9 is a graph of a neural network training incomplete factorial experiments as a function of score for the network based on the scoring scheme of Table 5, where actual values are depicted as a solid line and network predicted values are depicted as a hashed line;

FIG. 10 is a graph of a neural network crystallization predicted scores derived from experiments unseen by the trained network of FIG. 9 where predicted scores are depicted as hashed lines, as compared to actual measured scores depicted as solid lines;

FIG. 11 is a bar graph illustrating the relative importance of various crystallization input values as determined for Delta 8-10B protein derived from FIGS. 9 and 10;

FIG. 12 is a graph of neural network training incomplete factorial experiments as a function of score for the network based on the scoring scheme of Table 8 where actual values are depicted as a solid line and network predicted values are depicted as a hashed line;

FIG. 13 is a graph of neural network crystallization predicted scores derived from experiments unseen by the trained network of FIG. 12 where predicted scores are depicted as hashed lines, as compared to actual measured scores depicted as solid lines; and

FIG. 14 is a bar graph depicting the relative importance of input variables for the crystallization experiments depicted in FIGS. 12 and 13.

### DETAILED DESCRIPTION OF THE PREFERRED EMBODIMENTS

The present invention has utility as a process for optimizing crystallization conditions for a variety of substances. The present invention includes self-learning programs based upon neural networks and/or smart algorithms that divine optimal crystallization conditions. The operation of these programs is preferably combined with a high-throughput automated screen preparation liquid dispenser that physically creates the customized conditions for each sample. A neural network and/or a smart algorithm according to the present invention provides a novel understanding of the highly non-linear crystallization process, thereby reducing the number of required experiments, and needed quantities of experimental samples. With the present invention operating to automatically prepare the screening experiments, human error is also eliminated. The reduction in the time required to create crystallization recipes speed the structure-based drug design cycle or other crystallization related activities.

While the present invention is described with respect to protein crystallization, it is appreciated that the present invention is operative in the optimization of crystallization conditions for a variety of potential crystallant substances illustratively including organic molecules, organometallic molecules, inorganic molecules, nanocrystals, and viruses. An inventive crystallization process speeds structure-based drug design by expediting the crystallization of protein crystals, as well as by revealing the crystallization process itself, thus allowing investigation of variables important for crystallization. The innovative crystallization functions are based on neural networks that use every outcome in the training process, so even “clear drop”, “phase change” and “precipitate” crystallization experiment results contribute information to the self-learning functions.

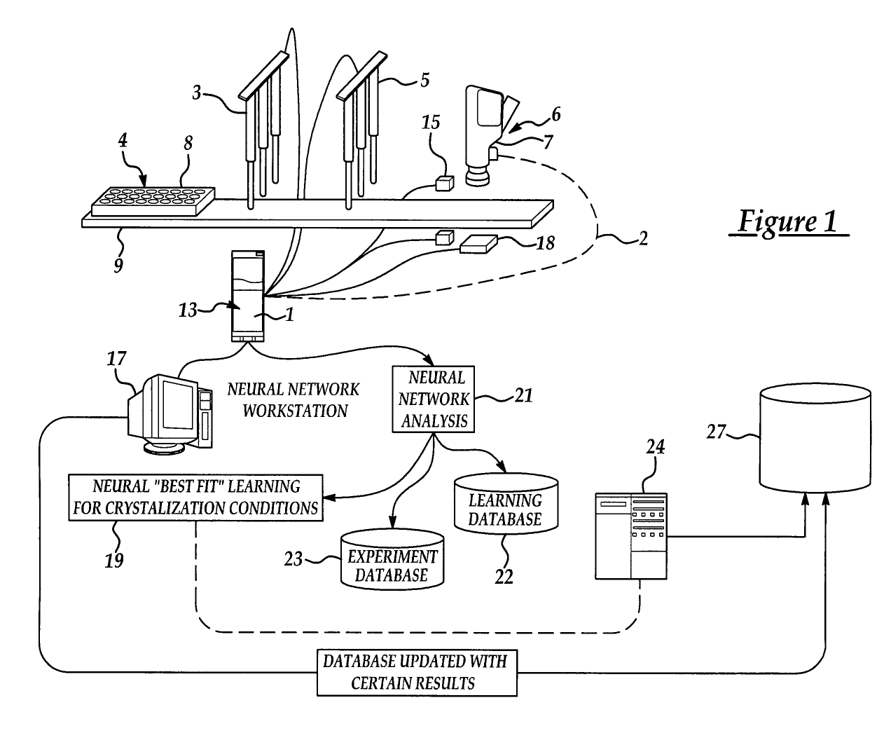

The components of a preferred automated system according to the present invention are shown in FIG. 1 and include a software interface 2 that allows for crystallization screens to be designed using an incomplete factorial method for sampling the user defined variable space, and physically created by the hardware component, such as a commercial available liquid dispenser 3 such as a Microlab MPH 96 with 96 probe heads (Hamilton Instruments, Reno, Nev.). The liquid dispenser 3 will automatically pipette the incomplete factorial designed screen into user selectable sample carrier tray plates 4 in volumes of up to several milliliters. An additional dispenser 5 pipettes a crystallant sample, such as a protein into the tray plates containing the screen components or alternatively, the protein is premixed with the screen with the liquid dispenser 3. The incomplete factorial systematically samples the entire experimental space. For example, a ten variable experimental space represented by 47 components has 328,050 possible experimental permutations. This crystallization parameter space can be statistically sampled with 300-500 experiments. The ability to automatically design and physically create incomplete factorial screens for use with any crystallization dispenser is complemented by the predictive crystallization functions. After the protein crystallization images from a crystal imaging system are screened with the initial incomplete factorial screen, every outcome is entered into the inventive system software either manually or automatically through an XML interface such as CrystalScore™ (Diversified Scientific, Inc., Birmingham, Ala.), to provide the automatic image acquisition, analysis, and archiving solution for protein crystallization experiments.

Preferably, a camera 7 utilized in an inventive crystal imaging system 6 has a digital output signal, such as that collected by a charge coupled device equipped with a frame grabber, although it is appreciated that an analog specimen image is readily operative herein using conventional image manipulation techniques.

A crystal examined according to the present invention is detailed herein as occurring in a crystallization tray plate 4. It is appreciated herein that other crystallization media well known to the art are also operative herein. Suitable crystallization media include conventional glass and plastic slides, plates and tubes, as well as silicon based chips and arrays, or other suitable platforms that allow for controlled evaporation.

In an alternate embodiment, the crystallization media is held in a stationary position and an inventive camera moves relative thereto. An indexing system of markings relative to a crystallization well or other conventional alignment schemes are utilized to assure proper orientation and illumination relative to the well. The position of a camera relative to a crystallization well is precisely controlled using a track or arm interfaced by way of a stepper motor or the like.

It is appreciated that the inventive system is operative in not only a conventional camera placed over a specimen arrangement, but also in an inverted geometry or a side-by-side arrangement therebetween.

In a preferred embodiment, a robotic handler 9 is utilized to manipulate crystallization media such as a tray plate 4 into a spatial area in which the imaging system 7 is capable of image acquisition. The crystallization media-grasping portion of a robotic handler is appreciated to be dependent upon the dimensions and grasping protuberances thereof. In a particular embodiment, conventional crystallization tray plates 4 are manipulated by a robotic handler 9 so as to be placed within the spatial acquisition area of the camera for imaging and thereafter removed. Crystallization media in this way can be sequentially examined with minimal human intervention. In a preferred embodiment, a robotic handler 9, if present, a movable camera, or movable tray is under feedback control of a camera-centering algorithm of imaging software 11 relative to a preselected crystallization site. The algorithm operates on an initial camera image to calculate the center of and focus of, for example, a crystallization well. The deviation between the center of the crystallization well and the camera image is transmitted to an appropriate hardware translation stepper motor (not shown) in order to align the center of the crystallization well with the center of the imaging field. Camera focus is preferably determined through collection of a movie collected as a function of focus with an autofocus algorithm determining image collection focus. Alternatively, a manual override of the focusing aspect or any other function defined herein as automatically performed by an algorithm run by a processing unit occurs at the option of an operator. Optionally, the algorithm 11 also serves to identify the liquid drop from which crystallization is hoped to occur. The drop size is used to compute factors relevant to crystallization analysis illustratively including drop volume, evaporation rate, deviation of crystallization nucleus from well center, and crystallization solution turbidity. Camera image data illustratively including turbidity, straightness of crystal edges, crystal defect assessment, fractures in the crystal, crystal size and the like are combined to bin a crystallization outcome to one of a predetermined number of states. Information classified according to the preselected number of states is available for subsequent analysis, refinement of classification states, and evaluation of crystallization scoring formulas. A crystallization scoring system automatically evaluates a result signal representative of a specimen condition into one of multiple outcomes for a specimen drop crystallization experiment. While it is appreciated that any number of schemes are operative herewith, in a preferred embodiment a crystallization experiment outcome is binned into one of nine states including clear drop, phase separation, precipitate, microcrystal/precipitate, rosette/spherulite, needle, plate, small three-dimensional crystal and large three-dimensional crystal. In a preferred embodiment, a crystallization experiment is automatically scored by the inventive system. Alternatively, an operator manually enters a numeric code associated with each of a preselected number of crystallization experiment outcomes.

An inventive computer controlled crystal imaging software system 17 preferably includes scheduling software for periodic crystal image collection for particular crystallization experiments. Scheduling software is appreciated to further serve the function of obtaining information with respect to evaporation and crystal growth rates. In order to facilitate image collection for the large number of specimens associated with a typical crystallization study, an inventive system optionally includes a barcode associated with a crystallization medium. A barcode scanner associated with a robotic handler, if present, or a specimen stage assures proper specimen identification and operator data entry. Additionally, a barcode system scheduling of successive image collection representative of a particular specimen is accomplished without operator input.

In order to ensure even illumination of the crystal specimen during the image acquisition by the imaging system 7, preferably a fiber optic lighting system 30 is utilized as a back light under the tray plate 5. In one embodiment, the computer 13 running the imaging software 11 can control the intensity of the lighting system 15, as well as the presence of light. Additionally, the computer 13 can also control polarizing means, such as the angle of polarization. It is appreciated that specimen lighting conditions and wavelengths are any of those conventional to the art that yield information about crystallization. Specimen illumination is either monochromatic or polychromatic, and varies between infrared and x-ray wavelengths. Additionally, specimen illumination is by direct lighting, reflective lighting or backlighting. In a preferred embodiment, lighting parameter control is by way of a control unit that automatically provides illumination having preselected characteristics. More preferably, the control unit has a sensor 19 affording feedback modulation of actual lighting characteristics relative to preselected characteristics.

In a preferred embodiment a manufacturing execution system such as a computer 13 running CrystalScore™ imaging software 11 is in communication with the predictive crystallization network computer 17 running a predictive neural network analysis 21 so that training experience is fed back into the choice of input variables.

An experimental sample variable information and crystallization results communicated by the imaging software 11 for neural network analysis 17 results in a trained network capable of predicting crystallization experimental conditions. The neural “best fit” learning conditions 19 are communicated to from the neural network computer 17 back to the manufacturing execution system 13 in order to update experimental design for optimal crystallization. Training results of the analysis 21 are also preferably stored in a learning database 22 and an experimental database 23. The learning database is operative in studying and improving neural network analysis algorithms. Similarly, the experimental database 23 is operative in storing for subsequent analysis information relevant to the particular protein such as variable related parameters.

In a preferred embodiment, optimal crystallization conditions 19 are transmitted via Internet or other conventional networking mode to a server 24 housing a shared database 27 of protein relevant data. Additional actual successful crystallization data is communicated to the server 24. The shared database 27 includes information illustratively including protein expression gene; protein characteristics; protein class hierarchy; actual protein chemical structure including primary, secondary, tertiary and where applicable quaternary structures; protein crystal generation recipe parameters; and optimal crystallization screen design. The ability to access the shared database 27 affords a user an opportunity to draw on related protein information relative to a protein of interest in order to expedite experiment design and optimal crystallization.

The present invention utilizes every outcome, including failures, to create a crystallization function that describes the various states of crystallization for the protein in terms of real, physical variables. This software then feeds the crystallization function every possible combination in the complete user-defined factorial experiment. Some user selected number, for example, the top 20 highest predicted crystallization outcomes from all the possible permutations. Preferably, the highest outcome conditions are then automatically created and used for generating optimization recipes that are anticipated to promote high-quality crystal growth. The resulting crystals are suitable for a variety of uses including x-ray diffraction.

Preferably, an inventive crystallization process uses as a predictive crystallization functions neural network an algorithm capable of predicting likely successful crystallization outcomes, based on an incomplete yet representative sampling of the permutation space. Operative algorithms illustratively include Chernov algorithms, Bayesian nets, Bayesian Classification, Bayesian Decomposition, and cluster analysis. The decomposition analysis includes all data, failures and successes, over time and return families or clusters of like responses. Moloshok, T. D., Klevecz, R. R., Grant, J. D., Manion, F. J., Speier, W. F., and Ochs, M. F. 2002. Application of Bayesian Decomposition for analyzing microarray data. Bioinformatics, 18(4):566-575. An operative inventive neural network looks for patterns in training sets of data, learns these patterns, and develops the ability to correctly classify new patterns or makes forecasts and predictions. The operative algorithms create a set of basis multiplying functions for each input variable. The operative algorithm such as a neural network, a Chernov algorithm, a Bayesian type algorithm, a Mahalanobis distance, or a Gram-Schmidt algorithm, is trained with the initial incomplete factorial screen. The user-defined variables of the incomplete factorial become the independent training variables. The outcome or score becomes the dependent variable. Once trained, both functions are used to predict the highest outcomes for crystallization from the entire factorial space even though only about 0.1% of the factorial space is initially tested. Typically, less than 5% of the factorial space is tested; often less than 1% is tested, and in many instances, less than 0.1% is tested. The quality of testing required is appreciated to be a function of variables illustratively including input variable correlation with crystallization and input variable interdependency.

According to the present invention, initial crystallization parameter design is performed by a user with inputs as to various variables and ranges therefor. The imaging software 11 accounts for the number of variables V and the number of index values each variable V can assume, as shown for a representative scenario in Table 1. The imaging software 11 then performs experimental samplings based on a user specified protocol as described herein. The software 11 drives a variety of commercially available system hardware components illustratively including a dispenser 3 or 5, a tray plate 4, a robotic handler 9, an imaging system 6, and a lighting system 15.

After the neural network training portion of the experimental samples is completed, a user interface through a computer provides visualization of each sample experiment, if desired, and an optional tabular report summarizing variable indices, scoring and drop description. The report data from the visualization with or without user modification is processed through an inventive neural network analysis 17. The analysis 17 in addition to yielding optimal variable conditions for crystallization also feeds results to the shared database 27 in order to serve at least one function from among: creation of protein classes based on neural network analysis; identification of common physical properties of proteins within a crystallization class; comparison of known physical properties of new unscreened targets to those in at least one crystallization class and automatic creation of targeted optimization screens developed for individual crystallization classes so as to bypass initial broad experimental samples; prediction of crystallization variables for every permutation and the correlation of predictions between various proteins, with correlations used to assemble crystallization classes; determination of protein classification through the usage of neural network basis functions, Chernov multiplying functions or other inventive functions; and the creation of a distance measurement such as a Mahalanobis distance indicative of input variable and outcome between proteins.

Spatial correlation template matching between the responses of different proteins to the same screen on an experimental sample by experimental sample basis provides a spatial distance relationship score. The correlation yields a distance score between two proteins. As a measure of how well a protein correlates to a second protein crystallization score, a distance function can be used between the two proteins. The index i represents each experimental sample, so for example 360 different conditions, so I=1 to 360. The distance function compares the response of the protein to each screen condition. If the response is identical, the resultant spatial value becomes 1. If the response is different, the resultant spatial value becomes 0. The correlation between the two proteins then becomes the sum of the resultant spatial values. Alternatively, real multiplication can be assigned for comparisons, i.e. if Protein 1 responds with large crystals to experimental sample 241 and Protein 2 responds with small crystals to experimental sample 241, the resultant spatial value could become much higher than 1. If a crystal is scored as 1000, then the resultant score of crystals at the same condition in two proteins becomes 1000×1000=1,000,000. The classification system is organized by comparing every protein on a one-by-one basis to other proteins. Neighborhoods and families are then organized by relative closeness.

Measurements are collected, indicating, for example numbers of particles, size of particles, straight edges, image color, Fourier analysis metrics from each image. These measurements form a vector. The vectors can then be clustered using a variety of analyses. Analyses detailed herein such as neural nets, Chernov algorithms, or a Bayesian classification schema operate to cluster the vectors. Results from crystallization experiments tend to have common characteristics that the analysis identifies. Those metrics or measurements that contain useful information differ depending upon the resolution of the images collected but the analysis or image classification algorithm still operates in a similar manner.

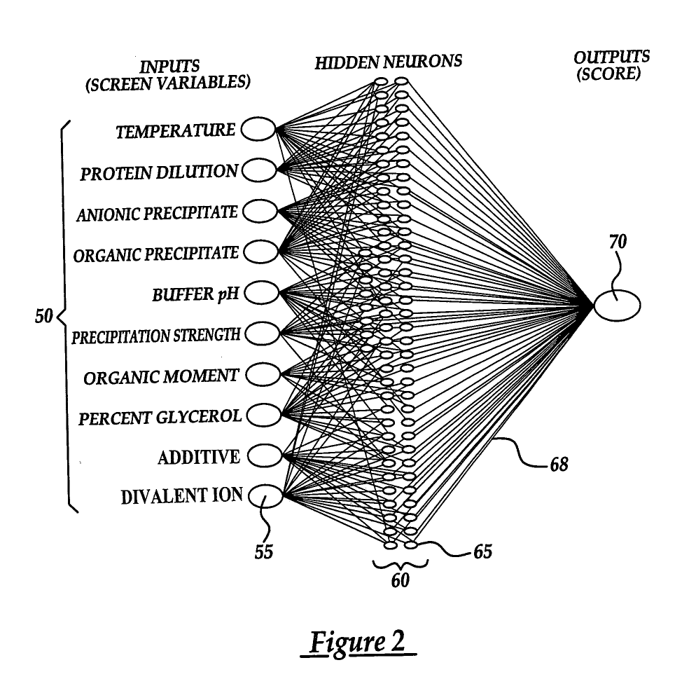

An inventive predictive neural network is trained, by back propagation, using a test set to identify or recognize important features, as shown in FIG. 2. Training an inventive neural network begins by finding linear relationships between the network inputs 50 and the output 70. Weight values are assigned to the links between the input and output neurons. After those relationships are found, neurons are added to the hidden layer 60 so that nonlinear relationships can be found. Input values 50 in the first layer 55 are multiplied by the weights and passed to the hidden layer 60. Neurons 65 in the hidden layer 60 produce outputs that are based upon the sum of weighted values passed to these neurons 65. The hidden layer 60 passes values 68 to the output layer 70 in the same fashion, and the output layer 70 produces the desired predictions. The network “learns” by adjusting the interconnection weights between layers. The answers the network is producing are repeatedly compared with the correct answers, and each time the connecting weights are adjusted slightly in the direction of the correct answers. Preferably, additional hidden neurons are added to capture features in the data set. Eventually, if the problem is learnable a stable set of weights evolves and produces good answers for all of the sample decisions or predictions. The real power of an inventive neural network is evident when the trained network is able to produce good results for data that the network has never evaluated to predict the conditions that produce crystals from the entire experimental factorial space. (Ward Systems Group “Neuroshell Predictor.” 2000. www.wardsystems.com).

The Chernov algorithm is structured similarly to a regression model, but instead of coefficients, the algorithm uses mathematical basis functions that can be linear or non-linear, discrete or continuous. The mathematical basis functions take into account higher-order interactions between the various components, so variables within a multiplying basis function may contain variables from other input functions. The mathematical functions are automatically varied in an organized procedure until the r squared value, or coefficient of determination, which is basically a measure of the difference between observed and computed values, is within an acceptable range. Typically, the accepted range is usually greater than 0.95. Once trained, the Chernov algorithm mathematically describes the various states of crystallization (output) in terms of real, physical variable inputs, as shown in Equation 1.

F₁V+F₂*V₂+F₃*V₃+ . . . Fₙ*Vₙ=Output (Eqn. 1)

where Fₙ are mathematical basis functions that can be linear or non-linear, discrete or continuous, Vₙ are input variables, and Output is the predicted score.

A Chernov sampling algorithm operative herein for initial experimental sample analysis operates as follows. For example, if a variable assumes three values and 300 experiments are sampled, then each value is taken, on the average, 100 times. If the actual frequencies of those values are 299,300,301, then the deviation from the mean are −1, 0, 1, the sum of squares is 1+0+1=2, hence the root mean square is sqrt(2/3), after accounting for three possible values. For a parameter space with several variables that take several possible values each, then the inventive algorithm finds the overall root mean square for all actual frequencies. This quantity characterizes the uniformity of the distributions of individual variables. Ideally, the overall root mean square should be zero, but small values of typically less than or about one are also operative.

Similarly, the screening algorithm finds the root mean square deviation for pairs of variables. For example, if two variables each assume three values and five values, respectively, and 300 experiments are sampled, then each pair of values is taken, on the average, twenty times. Now, let the actual frequencies be, say, 20, 21, 22, 20, 17, 20. Then the deviations from the mean are 0, 1, 2, 0, −3, 0, and the sum of squares is 1+4+9=14. The root mean square is sqrt(14/15). For a parameter space with several variables that take several possible values each, then the inventive algorithm finds the overall root mean square for all actual frequencies for all pairs of variables. This quantity characterizes the uniformity of the joint distributions of pairs of variables. Ideally, the overall root mean square should be zero, but small values of typically less than or about one are also operative.

A similar analysis is performed for treble variables. It is appreciated that this analysis is readily extended through n-dimensional variables.

For the present example there are three quantities: S1, S2, S3, which are root mean square deviations for 1-variable distributions, 2-variable distributions, and 3-variable distributions, respectively.

A combined quantity S is defined as:

S=w1*S1+w2*S2+w3*S3

where w1, w2, w3 are weights that are either set by the user, fixed, or calculated based on external crystallization factors.

In implementation a computer program constructs the prescribed number of samples “in one sweep”, without further reconstruction or modification of experimental data. This is in contrast to numerous conventional algorithms that select some experiments randomly or by a quick simple procedure, and then modify the experiments in order to improve their distribution. The inventive algorithm constructs samples sequentially, in one run, and preferably does not change the initial choice. The near uniformity of the distribution is achieved by a careful organization of the algorithm.

Table ______ compares the results from the above algorithm with those generated by human choice.

TABLE

| | Actual (DSI) | | | Present Invention | | |
|---|---|---|---|---|---|---|
| Experiment | S1 | S2 | S3 | S1 | S2 | S3 |
| Test A | 0.00 | 6.94 | 4.73 | 0.00 | 0.84 | 1.97 |
| (9 variables, 900 experiments) | | | | | | |
| Test B | 0.00 | 3.34 | 2.19 | 0.00 | 0.92 | 1.43 |
| (10 variables, 360 | | | | | | |
| experiments) | | | | | | |
| Test C | 4.64 | 2.05 | 0.69 | 0.39 | 0.61 | 0.42 |
| (11 variables, 288 | | | | | | |
| experiments) | | | | | | |
| Test D | 34.93 | 16.87 | 8.06 | 0.00 | 0.89 | 2.11 |
| (10 variables, 1032 | | | | | | |
| experiments) | | | | | | |

The inventive program generated algorithms more uniformly distributed experiment samples than those selected by a skilled operator.

In addition to the protein crystallization screen variables depicted in FIG. 1, other variables are readily tested as to effect on crystallization. These additional variables illustratively include light, magnetism, gravity, atmosphere identity, atmospheric pressure, and second virial coefficients. For example, with respect to gravity, it can be used as a design variable in the incomplete factorial design and subsequent optimization in much the same way as any variable such as pH or temperature. By setting the incomplete factorial to include two possible values of gravity, an inventive function calculates and creates screen experiments for earth and space gravity values. After the initial experiments are performed, the present invention analyzes all the results, predicts the combination of variables that yield the optimal crystallization parameter outputs, and creates the optimizations screens. These optimization experiments require the use of gravity in situations where gravity is a major factor to the protein crystallization sample.

The invention is further detailed with respect to the following non-limiting examples. These examples are not intended to limit the scope of the appended claims to the illustrative materials and conditions detailed herein.

### EXAMPLE 1

Crystallization recipes were developed using 10 variables and 47 components, as shown in Table 1 and have 328,050 combinations of components.

The screening results for modeling protein crystallization from a single protein were collected and subjected to three types of analysis. The screening results from lactoglobulin and protein 9c9 were selected as test cases for analysis. Lactoglobulin gave a frequency of forming crystals of 3.1-5.8% depending on the screen used. The three types of crystallization analyses used for lactoglobulin are: (1) a conventional multiple step regression analysis, (2) an inventive neural net analysis and (3) Chernov analysis. The multiple step regression analysis uses linear, quadratic and cross products were used to build a model based on the screening results. (Carter Jr., C. W., and Carter, C. W. Protein crystallization using incomplete factorial experiments. J. Biol. Chem. 1979, 254:12219-12223; Carter Jr., C. W. Response surface methods for optimizing and improving reproducibility of crystal growth. Methods in Enzymology 1997, 276: 74-99).

TABLE 1
Variables and Treatments Used for
Incomplete Factorial Screen (Lactoglobulin)

| Variable/Treatment | Index |
|---|---|
| Variable 1: Temperature | |
| 4° C. | 1 |
| 15° C. | 2 |
| 20° C. | 3 |
| Variable 2: Protein Dilution | |
| 4.382 | 1 |
| 3.912 | 2 |
| 3.442 | 3 |
| Variable 3: Anionic Precipitate | |
| Chloride | 1 |
| Citrate | 2 |
| Acetate | 3 |
| Sulfate | 4 |
| Phosphate | 5 |
| Variable 4: Organic Precipitate | |
| MPD | 1 |
| PEG400 | 2 |
| PEG2000 | 3 |
| PEG4000 | 4 |
| PEG8000 | 5 |
| Variable 5: Buffer pH | |
| 5.5 | 1 |
| 6 | 2 |
| 6.5 | 3 |
| 7 | 4 |
| 7.5 | 5 |
| 8 | 6 |
| Variable 6: Precipitation Strength | |
| 3 | 1 |
| 5.47 | 2 |
| 9.97 | 3 |
| Variable 7: Organic Moment | |
| 0.05 | 1 |
| 0.4 | 2 |
| 0.75 | 3 |
| Variable 8: Percent Glycerol | |
| 0 | 1 |
| 5 | 2 |
| 10 | 3 |
| Variable 9: Additive | |
| None | 1 |
| Arginine | 2 |
| BOG | 3 |
| Variable 10: Divalent Ion | |
| None | 1 |
| Mg2 | 2 |
| Ca2 | 3 |

The scoring system emphasized crystals and deemphasized non-crystals. The test protein used was lactoglobulin (10 mg/ml, 100 mM Tris-HCl, pH 6.5). These recipes were mixed with the protein sample using a derivative of the batch method. The experiments were monitored over time and the results scored using CrystalScore™.

The conventional multiple step regression yields an R^{2 value} of 0.54, indicating the failure of this analysis to converge on the correct solution and highlighting the inapplicability of this model of protein crystallization where the four variables used were protein concentration, pH, temperature, and precipitant concentration. No further comparison was made with this analysis for 9c9 protein.

In contrast to the multiple step regression, the inventive neural network and Chernov analyses rely less on the quality of variables chosen and allow convergence to a self-consistent solution. Both neural network and Chernov analyses are useful to construct a model that will recognize combinations of reagents what will most likely give a selected score indicative of optimal crystallization.

It is appreciated that the mathematics of the trained neural network are operative to construct a hierarchy ordering classification system that groups related neural network crystallization models of different proteins based on nodal basis functions, nodal construction similarities, contribution of importance of input variables or the like. Such a classification system allows an uncrystallized protein to be placed into a crystallization group based on its known physical properties. Several techniques exist for placing an unknown protein into the correct crystallization group including the use of a separate neural network designed to optimize the fit between the unknown protein and the existing classification groups. In a preferred embodiment, the classification system is self-learning and self-organized by conventional techniques, thus, a small number of modeling proteins is sufficient to accurately predict optimal crystallization conditions for a large number of unknown proteins.

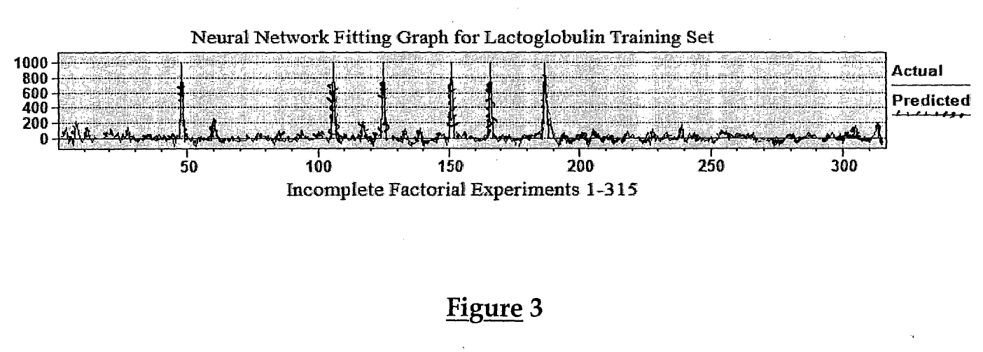

The neural network is trained only with lactoglobin experiments 1-315, as shown in FIG. 3. A representative sampling of the training set is shown in Table 2. Table 2 translates the incomplete factorial design in Table 1 to index values that represent the physical components of the crystallization recipe.

TABLE 2
Representative Training Data for Lactoglobulin Neural
Network (Experiments 1-315)

| Experiment | V1 | V2 | V3 | V4 | V5 | V6 | V7 | V8 | V9 | V10 | Score |
|---|---|---|---|---|---|---|---|---|---|---|---|
| 1 | 1 | 3 | 4 | 1 | 2 | 3 | 4 | 5 | 2 | 3 | 1 |
| 2 | 1 | 3 | 1 | 2 | 3 | 3 | 2 | 2 | 2 | 2 | 1 |
| 3 | 1 | 3 | 1 | 1 | 1 | 2 | 1 | 1 | 3 | 3 | 3 |
| 4 | 1 | 3 | 3 | 1 | 3 | 2 | 5 | 4 | 1 | 3 | 1 |
| 5 | 1 | 3 | 5 | 3 | 2 | 3 | 3 | 2 | 2 | 2 | 1 |
| . | . | . | . | . | . | . | . | . | . | . | . |
| . | . | . | . | . | . | . | . | . | . | . | . |
| . | . | . | . | . | . | . | . | . | . | . | . |
| 315 | 3 | 1 | 4 | 3 | 1 | 1 | 5 | 3 | 2 | 2 | 1 |

Experiments 316 to 360 are held out of the training and are used for output verification. The 315 experiments allowed the neural network to converge with an R² value of 0.754, an acceptable value, but still not optimal. The scoring system is listed in Table 3. A graphical representation of the neural network is shown in FIG. 2. The input to the neural network is the indexed variables and the output is the predicted score. The weights of the hidden neurons are determined by back propagation.

TABLE 3
Scoring System for Lactoglobulin

| Score | Descriptor |
|---|---|
| 1000 | Blue Crystals |
| 1000 | Large 3d crystals |
| 1000 | Small 3d crystals |
| 1000 | Plates |
| 1000 | Needles |
| 5 | Rosettes/Spherulites |
| 4 | Microcrystals/Precipitate |
| 3 | Precipitate |
| 2 | Phase Separation |
| 1 | Clear Drop |

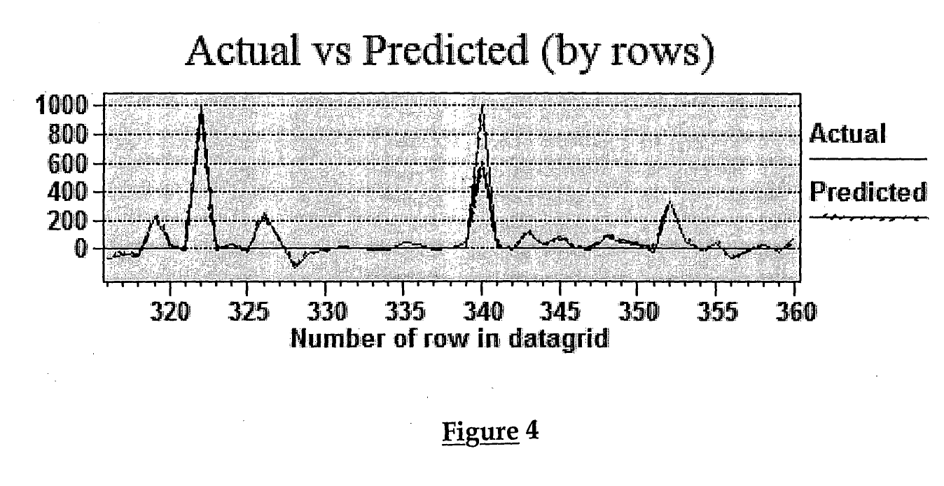

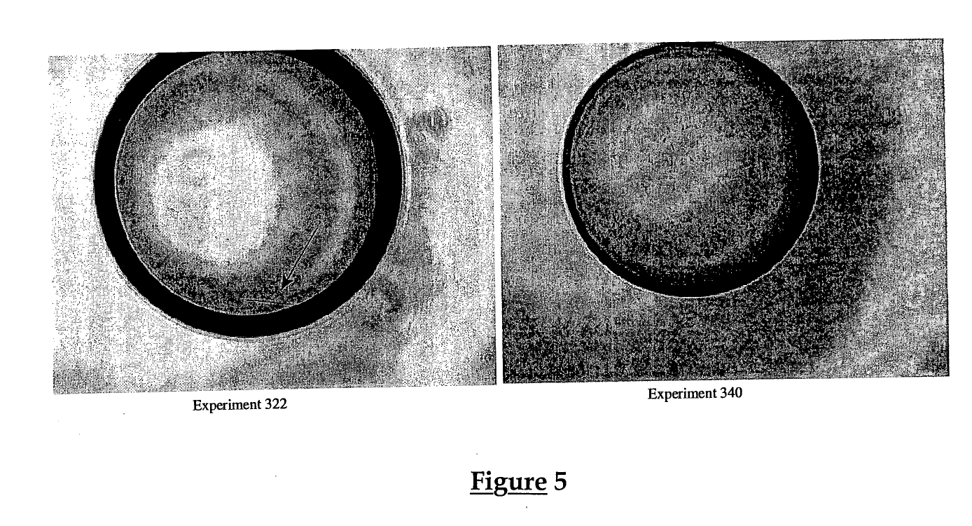

Experiments 316-360 had never been evaluated by the inventive neural network yet the neural network was able to predict every crystallization outcome of the 45 experiments, including the two crystallization outcomes for experiments 322 and 340 as shown in FIG. 4. Demonstrates that in experiments 316-360, the neural network successfully predicted the 2 crystal outcomes (experiments 322 and 340). FIG. 5 is photograph illustrating the actual physical crystallization outcomes of the two predicted crystallization conditions for experiments 322 and 340.

The Chernov algorithm converged on the lactoglobulin training set with a R² value of 0.93. The Chernov algorithm is used in a predictive manner to create optimization conditions for lactoglobulin protein crystallization. The highest 20 predictions out of the 328,050 permutations were created and are shown in Table 4. The Chernov analysis was only performed on lactoglobulin screen results. The Chernov analysis optionally is used to construct a model that will recognize combinations of reagents that will most likely give a selected score. Various scoring schemes are the tested, each scheme having a hierarchy built in, that is assigning a measure of importance to the out come in order to help the analysis programs identify variables important for a particular sample crystallization function. This is demonstrated by the enhanced scoring system used for the neural network that accurately predicted the crystallization conditions of lactoglobulin.

TABLE 4
Chernov Analysis: Lactoglobulin top 20 hits with higher-order input
variable interactions.*

| V1 | V2 | V3 | V4 | V5 | V6 | V7 | V8 | V9 | V10 | Score |
|---|---|---|---|---|---|---|---|---|---|---|
| 1 | 2 | 2 | 1 | 2 | 3 | 6 | 5 | 1 | 1 | 12.9 |
| 1 | 2 | 1 | 1 | 2 | 1 | 6 | 5 | 1 | 1 | 12.5 |
| 3 | 1 | 2 | 1 | 2 | 3 | 6 | 5 | 1 | 1 | 12.5 |
| 3 | 2 | 2 | 1 | 2 | 3 | 6 | 5 | 1 | 1 | 12.4 |
| 1 | 2 | 4 | 1 | 2 | 2 | 1 | 1 | 1 | 2 | 12.4 |
| 1 | 2 | 1 | 1 | 2 | 3 | 6 | 5 | 1 | 1 | 12.3 |
| 3 | 2 | 1 | 1 | 2 | 1 | 6 | 5 | 1 | 1 | 12.2 |
| 3 | 1 | 1 | 2 | 1 | 1 | 6 | 5 | 3 | 2 | 12 |
| 1 | 2 | 3 | 1 | 2 | 1 | 6 | 5 | 1 | 1 | 12 |
| 3 | 2 | 1 | 1 | 2 | 3 | 6 | 5 | 1 | 1 | 11.9 |
| 3 | 1 | 2 | 1 | 2 | 3 | 6 | 4 | 1 | 1 | 11.8 |
| 3 | 1 | 1 | 2 | 1 | 3 | 6 | 5 | 3 | 2 | 11.8 |
| 3 | 2 | 2 | 1 | 2 | 3 | 6 | 4 | 1 | 1 | 11.8 |
| 1 | 2 | 2 | 1 | 2 | 1 | 6 | 5 | 1 | 1 | 11.7 |
| 1 | 1 | 2 | 1 | 2 | 3 | 6 | 5 | 1 | 1 | 11.7 |
| 3 | 1 | 1 | 1 | 2 | 1 | 6 | 5 | 1 | 1 | 11.7 |
| 1 | 2 | 3 | 1 | 2 | 3 | 6 | 5 | 1 | 1 | 11.7 |
| 1 | 1 | 4 | 1 | 2 | 1 | 6 | 1 | 1 | 1 | 11.7 |
| 1 | 2 | 4 | 2 | 2 | 2 | 1 | 1 | 1 | 2 | 11.7 |
| 3 | 1 | 1 | 2 | 2 | 1 | 6 | 5 | 3 | 2 | 11.7 |

*The score displayed here is a predicted score. These experiments were selected out of a total of 328,050 using the Chernov analysis. Variable interactions were allowed and the original scores (1-10) from the lactoglobulin experiment screened were used.

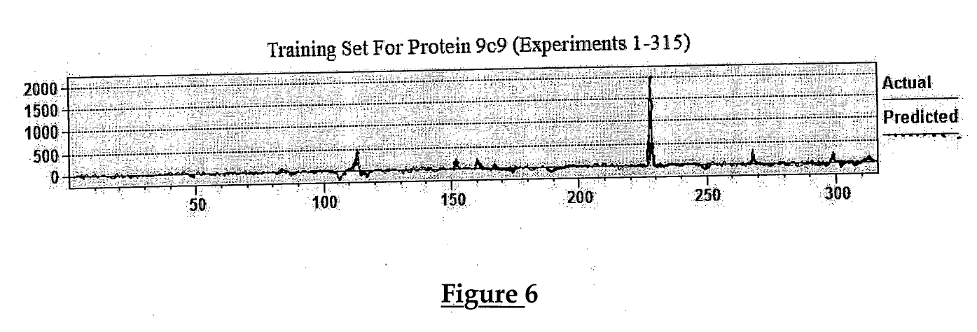

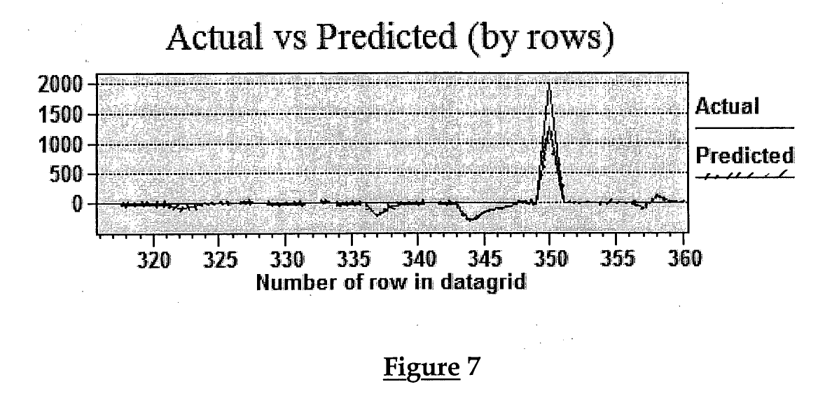

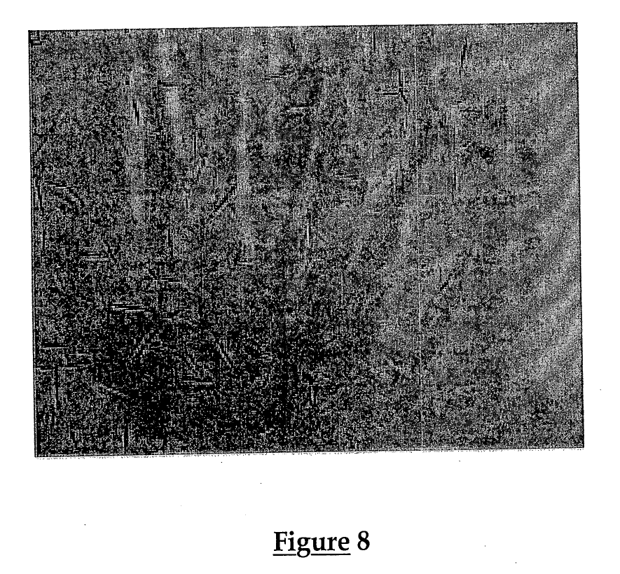

A similar methodology to lactoglobulin was used for an unknown purified protein, a previously uncrystallized sample. For the unknown purified protein, experiments 1-315 were used to train the neural network. There was only one crystal condition in the training set (experiment 239), as shown in FIG. 6. The neural network converged with an R² value of 0.604. The assigned scoring system was binary: No-crystal 0, Crystal 2000. Experiments 316-360 were used to verify the neural network. The trained neural network accurately predicted the only crystal yielding experiment (experiment 350), as shown in FIG. 7. FIG. 8 is a photograph illustrating the actual physical crystallization outcomes of the predicted crystallization conditions for experiment 350.

### EXAMPLE 2

A neural network was trained on 90% (259 experiments) of the randomized test set for Protein Delta 8-10B. The trained neural network is applied on the remaining ˜400,000 conditions not tested and then take the top 20 predicted scores for optimization.

An incomplete factorial screen with 11 input variables was designed for Protein Delta 8-10B. This protein is considered a peripheral membrane protein that has undergone attempts of crystallization. It is a therapeutically important protein whose structural data would be of great interest to the scientific community. The incomplete factorial was composed of 288 experimental samples. The incomplete factorial screen yielded the following outcomes: 226 clear drops, 3 phase separation, 39 precipitate, 10 microcrystals/precipitate, 8 rosettes/spherulites, 2 needles, 0 plates, 0 small 3d crystals, and 0 large 3d crystals. These outcomes were scored using the scoring system of Table 5.

TABLE 5
Scoring System for Delta 8-10B

| Score | Descriptor |
|---|---|
| 9 | Large 3d crystals |
| 8 | Small 3d crystals |
| 7 | Plates |
| 6 | Needles |
| 5 | Rosettes/Spherulites |
| 4 | Microcrystals/Precipitate |
| 3 | Precipitate |
| 2 | Phase Separation |
| 1 | Clear Drop |

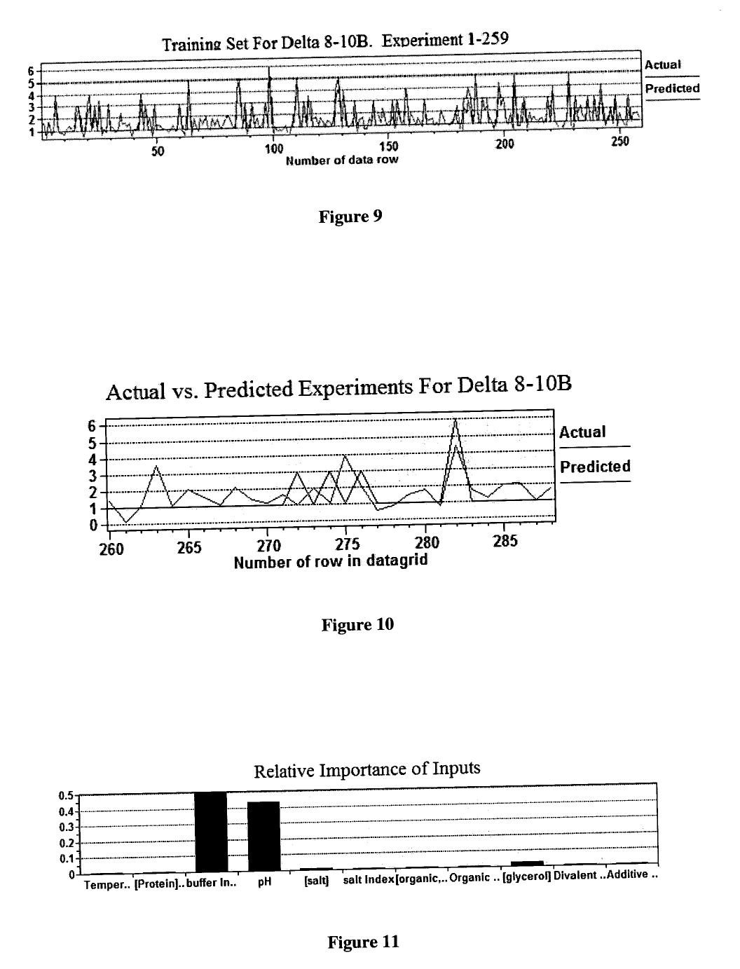

A partial set of screen for protein Delta 8-10B is shown in Table 6. The variables V1-V11 become the independent inputs while the score becomes the dependant output of the neural network. Experiments 1-259 were used to train the neural network as shown in FIG. 9. Experiments 260-288 were used to test the validity of the training as shown in FIG. 10. The relative importance of input variables is shown in FIG. 11 where buffer index and pH are the most significant variables.

Experiments 260-288 are used to verify the neural network. The inventive network was able to predict the crystallization condition for the only crystal in the test set (Experiment 282) even though it had never been trained on the experiment. There were two false positives (Experiment 263 and 275) although the relative highest predicted score is for the correctly predicted crystal condition.

TABLE 6
A partial set of the incomplete
factorial screen used for protein Delta 8-10B

| | [Protein], | buffer | | | salt | | Organic | | Divalent | Additive | |
|---|---|---|---|---|---|---|---|---|---|---|---|
| Temp | dilution | Index | pH | [salt] | Index | [organic, | Index | [glycerol] | Index | Index | |
| V1 | V2 | V3 | V4 | V5 | V6 | % = V7 | V8 | V9 | V10 | V11 | Score |
| 22 | 2.3 | 4 | 8.3 | 0.555 | 3 | 11 | 6 | 3 | 3 | 3 | 1 |
| 14 | 2.3 | 2 | 6.5 | 0.231 | 2 | 18.8 | 5 | 3 | 2 | 3 | 1 |
| 14 | 1.5 | 3 | 7 | 0.229 | 5 | 18.3 | 1 | 3 | 1 | 1 | 1 |
| 22 | 3.7 | 1 | 4.5 | 0.11 | 2 | 9.4 | 4 | 6 | 1 | 1 | 1 |
| 22 | 1.5 | 4 | 8.3 | 0.648 | 2 | 11.5 | 1 | 6 | 1 | 1 | 1 |
| 14 | 3.7 | 4 | 8.3 | 0.264 | 6 | 5.2 | 6 | 0 | 3 | 2 | 3 |
| 4 | 1.5 | 2 | 6 | 0.188 | 3 | 15.1 | 1 | 0 | 3 | 2 | 1 |
| . | . | . | . | . | . | . | . | . | . | . | . |
| . | . | . | . | . | . | . | . | . | . | . | . |
| . | . | . | . | . | . | . | . | . | . | . | . |

TABLE 7
Comparison of Experimental Conditions that Yield Crystals for Delta 8-10B

| | Tem- | [Pro- | | | | | | | | | | | | | |
|---|---|---|---|---|---|---|---|---|---|---|---|---|---|---|---|
| Experi- | pe- | tein], | | | | | | [organic, | | [glyce- | [Diva- | | [Addi- | Addi- | |
| ment | rature | dilution | [buffer] | Buffer | pH | [salt] | Salt | %] | Organic | rol] | lent] | Divalent | tive] | tive | Score |
| Trained | 14 | 2.300 | 0.100 | M | 8.3 | 0.567 | M Na | 0.9 | % PEG400 | 0.0 | 0.010 | M | 0.050 | % | 6 |
| | | | | Bicine | | | Acetate | | | | | CaCl2 | | BOG | |
| Pre- | 22 | 1.500 | 0.100 | M | 4.5 | 0.648 | M Na | 11.6 | % | 0.0 | 0.010 | MCaCl2 | 0.000 | None | 6 |
| dicted | | | | Acetate | | | Chloride | | PEGM5000 | | | | | | |

A neural network, trained by 90% (259 experiments) of an incomplete randomized test factorial screen for Delta 8-10B, is able to predict the only crystallization condition in the remaining 10% (29 experiments) of the incomplete factorial screen. The 90% test set contained only 1 needle condition while the test set contained only 1 needle condition. The neural network is able to predict the crystallization condition of the needle in the test set even though the 2 needles crystallized with very disparate conditions as shown in Table 7. The neural network trained with all results, including failures. The ability of the neural network to identify patterns of crystallization in complex non-linear datasets is a powerful method of optimization.

### EXAMPLE 3

A neural network was trained on 87.5% (315 experiments) of the randomized test set for Catalase. The remaining 12.5% (45 experiments) of the test set was used for verification. There were 13 crystals in the verification set. The top 15 neural network predictions included 12 of the 13 crystals in the verification set.

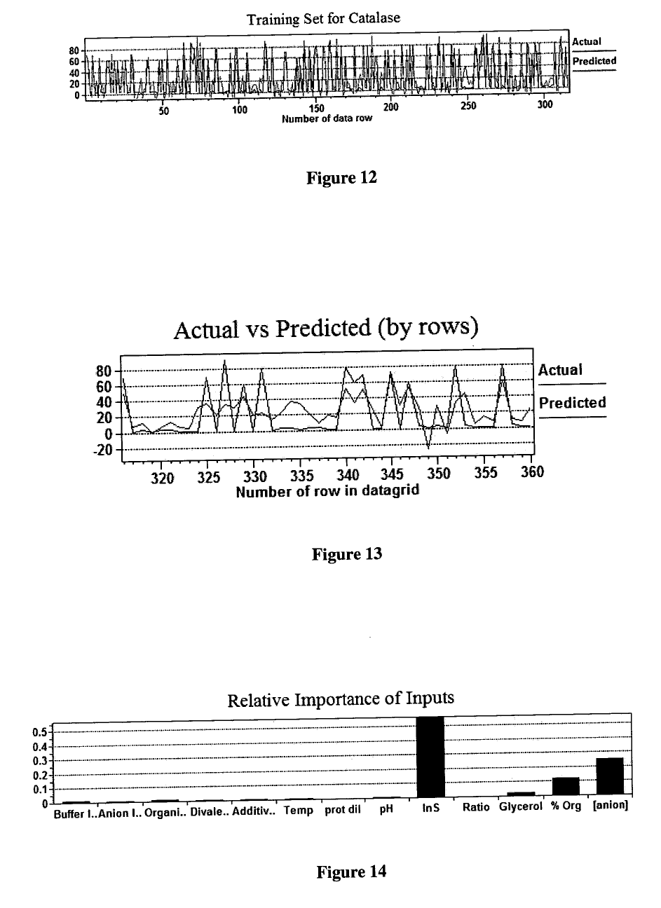

An incomplete factorial screen with 13 input variables was designed for Catalase. The incomplete factorial was comprised of 360 experimental samples. The outcomes were scored using the scoring system shown in Table 8. The incomplete factorial matrix was randomized by sorting on a column of randomized numbers in Excel®. The first 315 experiments were used to train the neural network as shown in FIG. 12. The training converged with an R squared value of 0.744 and a correlation of 0.863. The validity of the neural network was then verified by the remaining 45 out-of-sample experiments as shown in FIG. 13. The out-of-sample experiments had an R squared value of 0.439 and a more meaningful correlation value of 0.675.

TABLE 8

| Score | Descriptor |
|---|---|
| 90 | Large 3d crystals |
| 80 | Small 3d crystals |
| 70 | Plates |
| 60 | Needles |
| 5 | Rosettes/Spherulites |
| 4 | Microcrystals/Precipitate |
| 3 | Precipitate |
| 2 | Phase Separation |
| 1 | Clear Drop |

The top 15 neural network predictions included 12 of the 13 crystals in the verification set shown in FIG. 13. The 3 false positives included 2 precipitate conditions and 1 clear drop condition. The false negative (13^{th} crystal) occured at the 23^{rd} highest predicted score. The relative “importance of inputs” is shown in FIG. 14. InS, anionic concentration, % Organic, and Glycerol %, are the respective most important variables for crystallization of Catalase.

Publications cited herein are indicative of the level of skill in the art to which the invention pertains. Each publication is hereby incorporated by reference to the same extent as if each publication was individually and explicitly incorporated herein by reference.

The foregoing description is illustrative of particular embodiments of the invention, but is not meant to be a limitation upon the practice thereof. The following claims, including equivalents thereof are intended to define the scope of the invention.

1. A crystallization parameter optimization process comprising the steps of:
selecting a plurality of physical characterization input variables to define a total crystallization experiment permutation number for a crystallant;
performing a plurality of crystallization experimental samples, said plurality of crystallization experimental samples being less than the total crystallization experiment permutation number;
training a predictive crystallization function through analysis of said plurality of crystallization experimental samples; and
determining an optimal physical crystallization parameter from said predictive crystallization function.

2. The process of claim 1 wherein said predictive crystallization function is a neural network.

3. The process of claim 1 wherein said crystallant is a protein.

4. The process of claim 1 wherein each of said plurality of physical crystallization input variables is selected from a group consisting of: temperature, protein dilution, anionic precipitate, organic precipitate, buffer pH, precipitation strength, organic moment, percent glycerol, additive, divalent ion, gravity, light, magnetism, atmosphere identity, and atmosphere pressure.

5. The process of claim 1 wherein the plurality of crystallization experimental samples performed is less than 5% of the total crystallization experiment permutation number.

6. The process of claim 1 wherein the plurality of crystallization experimental samples performed is less than 0.1% of the total crystallization experiment permutation number.

7. The process of claim 1 wherein said predictive crystallization function analyzes a crystallization experimental sample as to a status selected from the group consisting of: clear drop, phase change, precipitate, and spherulettes.

8. The process of claim 1 wherein said predictive crystallization function trains through back propagation.

9. The process of claim 8 wherein said predictive crystallization function includes a hidden layer intermediate between input values and said optimal physical crystallization parameter.

10. The process of claim 1 wherein the performance of said plurality of crystallization experimental samples is automated.

11. The process of claim 10 further comprising the step of communicating said plurality of physical crystallization input variables between a manufacturing execution system performing said plurality of experimental samples and said predictive crystallization function.

12. The process of claim 1 further comprising the step of communicating said predictive crystallization function to a database.

13. The process of claim 12 wherein said database includes characteristics of a crystallization sample.

14. The process of claim 1 further comprising the steps of attempting crystal growth using said optimal physical crystallization parameter.

15. The process of claim 14 further comprising the step of communicating on said crystal growth attempt to a shared database.

16. The process of claim 15 further comprising the step of classifying said crystal growth attempt on a basis selected from the group consisting of: said optimal physical crystallization parameter, said predictive crystallization function, and a physical property of a crystallant.

17. The process of claim 1 wherein performing said plurality of crystallization experimental samples comprises the steps of:
controlling a plurality of variables where each of said plurality of variables assumes an index value or plurality of index values; and
performing a Chernov analysis to derive a minimized combined quantity representative of said total crystallization permutation number.

18. The process of claim 1 wherein said plurality of crystallization experimental samples are converted to vectors prior to the training of said predictive crystallization function.

19. The process of claim 18 further comprising the step of clustering said vectors.

20. The process of claim 19 wherein clustering occurs through the application of an analysis selected from the group consisting of: a neural net, a Chernov algorithm, a Bayesian net, a Bayesian classification schema, and a Bayesian decomposition.

21. A crystallization parameter optimization process comprising the steps of:
selecting a plurality of physical characterization input variables for a known crystallant to define a total crystallization experiment permutation number;
performing a plurality of crystallization experimental samples on said known crystallant;
training a predictive crystallization function through analysis of said plurality of crystallization experimental samples;
determining an optimal physical crystallization parameter for said known crystallant;
storing said optimal physical crystallization parameters and a physical property of said known crystallant sample in a classification system; and
comparing an unknown crystallization sample to the classification of said known crystallant.

22. The process of claim 21 wherein said predictive crystallization function is a neural network.

23. The process of claim 21 wherein said classification system is based on an aspect selected from the group consisting of: nodal basis functions, nodal construction similarities, and contribution of a particular physical characterization input variable.

24. The process of claim 21 wherein a comparative neural network relates said known crystallant and said unknown crystallization sample.

25. The process of claim 21 wherein said classification system is self-learning.

26. The process of claim 21 wherein said classification system is self-organized.

27. The process of claim 21 wherein each of said plurality of physical crystallization input variables is selected from a group consisting of: temperature, protein dilution, anionic precipitate, organic precipitate, buffer pH, precipitation strength, organic moment, percent glycerol, additive, divalent ion, gravity, light, magnetism, atmosphere identity, and atmosphere pressure.

28. The process of claim 21 wherein the performance of said plurality of crystallization experiments is automated.

29. The process of claim 21 further comprising the steps of attempting crystal growth using said optimal physical crystallization parameter.

30. The process of claim 21 wherein performing said plurality of crystallization experimental samples comprises the steps of:
controlling a plurality of variables where each of said plurality of variables assumes an index value or plurality of index values; and
performing a Chernov analysis to derive a minimized combined quantity representative of said total crystallization permutation number.

31. The process of claim 21 wherein storage occurs in a shared database wherein said shared database also stores at least one type of protein information selected from the group consisting of: protein expression gene; protein characteristics; protein class hierarchy; actual protein chemical structure including primary, secondary, tertiary and where applicable quaternary structures; protein crystal generation recipe parameters; and optimal crystallization screen design.

32. A protein crystal derived by the process of claim 1.

33. A neural network having been trained through analysis of a plurality of crystallization experimental samples to predict optimal crystallization conditions for a protein.

34. The network of claim 33 wherein said plurality of samples comprises samples failing to yield crystals.

35. A system for crystallization parameter optimization, the system comprising:
a database having a plurality of input variables, each of said plurality of input variables having a value range;
an incomplete factorial screen program having a trainable predictive crystallization function;
a computer capable of executing the incomplete factorial screen program to determine an optimal crystallization parameter; and
a manufacturing execution system for automatically acquiring of a datum from each of a plurality of crystallization experimental samples, analyzing and archiving of data from the incomplete factorial screen program.

36. The system of claim 35 wherein said manufacturing execution system controls at least one piece of crystallization hardware selected from the group consisting of: a liquid dispenser, a crystallant dispenser, a robotic handler, an imaging system, a sample centering motor relative to a camera focal plane, and a lighting system.

37. The system of claim 36 wherein said sample centering motor is coupled to at least one of: a sample stage and said camera for automatically positioning the specimen within the focal plane of said camera.

38. The system of claim 35 further comprising a barcode for indexing each of said plurality of samples.

39. The system of claim 36 further comprising a centering algorithm coupled to said motor for converging a central region of the specimen with a central region of the camera focal plane.

40. The system of claim 39 wherein said centering algorithm operates automatically.

41. The system of claim 35 further comprising a drop identification algorithm for evaluating a liquid drop associated with each of said plurality of samples.

42. The system of claim 41 wherein the liquid drop is classified into a preselected plurality of classes.

43. The system of claim 42 wherein said drop identification algorithm operates automatically.

44. The system of claim 36 wherein said motor is coupled to said camera.

45. The system of claim 36 further comprising scheduling software interfaced with said robotic handler.

46. The system of claim 37 wherein said scheduling software is interfaced with said sample stage.

47. The system of claim 35 further comprising a database that stores crystal relevant parameters.

48. The system of claim 47 wherein said crystal relevant parameters include at least one parameter of the group consisting of: crystal weight, crystal specimen pH, crystal specimen temperature, crystal specimen protein type, detergents present, additives present, preservatives present, reservoir buffer present, reservoir buffer concentration, reservoir buffer pH, crystal specimen volume, notes, crystal specimen score, and crystal specimen drop descriptor.

49. The system of claim 47 wherein said database is relational between said predictive crystallization function and said crystal parameters.

50. The system of claim 47 wherein said database is connected to a structured query language database.

51. A protein crystal derived from a system of claim 35.

52. A process according to claim 1 substantially as described herein in any of the examples.
